(19) United States
(12) Patent Application Publication
(10) Pub. No.: US 2024/0290583 A1
(43) Pub. Date: Aug. 29, 2024

(54) ELECTROSTATIC CHUCK, ELECTROSTATIC CHUCK HEATER COMPRISING SAME, AND SEMICONDUCTOR HOLDING DEVICE

(71) Applicant: AMOSENSE CO.,LTD, Cheonan-si, Chungcheongnam-do (KR)

(72) Inventor: Ji Hyung LEE, Cheonan-si, Chungcheongnam-do (KR)

(21) Appl. No.: 18/572,729

(22) PCT Filed: Jun. 29, 2022
(86) PCT No.: PCT/KR2022/009287

§ 371 Date: Dec. 20, 2023

(30) Foreign Application Priority Data
Jun. 29, 2021 (KR) 10-2021-0084527

(51) Int. Cl. H01J 37/32; H01L 21/683

(52) U.S. Cl. CPC H01J 37/32724; H01J 37/32477; H01L 21/6833; H01J 37/32807; H01J 2237/002; H01J 2237/2007

(57) ABSTRACT

An electrostatic chuck is provided. Implemented according to an embodiment of the present invention is an electrostatic chuck comprising: a silicon nitride sintered body; a silicon carbide (SiC) surface modification layer covering at least a portion of the external surface of the silicon nitride sintered body and having corrosion resistance and plasma resistance; and an electrostatic electrode laid inside the silicon nitride sintered body. Therefore, the electrostatic chuck includes a ceramic sintered body of silicon nitride, and thus has excellent plasma resistance, chemical resistance, and thermal shock resistance while exhibiting an equivalent or similar level of heat dissipation performance compared to ceramic sintered bodies of aluminum nitride that have been conventionally widely used, so that the electrostatic chuck can be widely used in semiconductor processes.

### TECHNICAL FIELD

The present invention relates to an electrostatic chuck, an electrostatic chuck heater and a semiconductor holding device including the same.

### BACKGROUND ART

Electrostatic chucks are used to adsorb and hold semiconductor wafers in the manufacturing processes of films such as the transport, exposure, chemical vapor deposition (CVD) sputtering of semiconductor wafers, and a series of steps such as microfabrication, cleaning, etching and dicing. As a substrate of such an electrostatic chuck, research on dense ceramics is being actively conducted. Particularly, in the devices for manufacturing semiconductors, halogen corrosive gases such as ClF₃ are often used as etching gases or cleaning gases. Additionally, in order to rapidly heat and cool a semiconductor wafer while holding in the chuck, it is required that the substrate of the electrostatic chuck has high thermal conductivity. Furthermore, such high thermal shock resistance that is not easily destroyed by such a rapid temperature change is also required. Moreover, as a plasma method is used for etching or deposition in a semiconductor process, the demand for a substrate of an electrostatic chuck having plasma resistance is increasing day by day.

However, aluminum nitride, which is widely used as a material for an electrostatic chuck substrate, has excellent heat dissipation characteristics, but is easily damaged by plasma in an etching or deposition process in which the plasma method is used during semiconductor processes, and there is a problem in that the durability is deteriorated. In addition, there is a problem in that cracks are frequently generated due to thermal shock. Moreover, there is a problem in that durability reduction due to plasma or thermal shock shortens the replacement cycle of an electrostatic chuck.

### DISCLOSURE

### Technical Problem

The present invention has been devised in view of the above points, and an object of the present invention is to provide an electrostatic chuck that has excellent heat dissipation characteristics while also having chemical resistance to chemicals such as corrosive gases applied during the semiconductor process, plasma resistance to plasma processing and thermal shock resistance due to rapid temperature changes, an electrostatic chuck heater and a semiconductor holding device including the same.

### Technical Solution

The present invention has been devised in view of the above points, and provides an electrostatic chuck, including a silicon nitride sintered body; a silicon carbide (SiC) surface modification layer covering at least a portion of the external surface of the silicon nitride sintered body and having corrosion resistance and plasma resistance; and an electrostatic electrode laid inside the silicon nitride sintered body

According to an exemplary embodiment of the present invention, the electrostatic chuck may have a relative etching rate of 0.9 nm/min or less when the etching rate of a Si wafer is 1.0 nm/min, under plasma environment with a power of 500 W or more, a mixed gas including 10 to 100 sccm of CF₄ gas, 0.1 to 50 sccm of O₂ gas and 1 to 70 sccm of Ar gas, and a pressure of 1 to 30 mTorr.

In addition, the silicon carbide (SiC) surface modification layer may be formed by modifying an external surface of the silicon nitride sintered body, and the modification may be performed by carburizing or oxidizing.

In addition, the carburizing may be performed for 5 to 35 hours at a temperature of 700 to 1,100° C. under a mixed gas including propane, ammonia, benzene and LPG.

In addition, the oxidizing may be performed for 30 to 300 minutes at a temperature of 500 to 1,300° C. under an air atmosphere.

In addition, the silicon carbide (SiC) surface modification layer may have a thickness of 0.2 nm or more.

In addition, the silicon nitride sintered body may be formed by sintering silicon nitride powder including 8 wt. % or less of polycrystalline silicon.

In addition, the silicon nitride sintered body may be formed by sintering phosphorus silicon nitride powder in which the weight ratio of an α crystal phase is 0.7 or more in the total weight of an a crystal phase and a β crystal phase.

In addition, the silicon nitride sintered body may have a thermal conductivity of 90 W/mK or more and a 3-point bending strength of 700 MPa or more.

In addition, the silicon nitride sintered body may be prepared by sintering silicon nitride powder, and the silicon nitride powder may be prepared by including the steps of preparing mixed raw material powder including metallic silicon powder and crystalline phase control powder which includes a rare earth element-containing compound and a magnesium-containing compound; mixing the mixed raw material powder with a solvent and an organic binder to form a slurry and then spray-drying to produce granules having a predetermined particle size; nitrifying the granules at a predetermined temperature within the range of 1,200 to 1,500° C. while applying nitrogen gas at a predetermined pressure; and pulverizing the nitrified granules.

In addition, the metallic silicon powder may be a dry-ground polycrystalline metal silicon scrap or single-crystal silicon wafer scrap to minimize contamination with metal impurities during pulverizing.

In addition, the metallic silicon powder may have an average particle diameter of 0.5 to 4 μm, the rare earth element-containing compound powder may have an average particle diameter of 0.1 to 1 μm, and the magnesium-containing compound powder may have an average particle diameter of 0.1 to 1 μm.

In addition, the granules may have a D50 value of 100 μm or less.

In addition, the rare earth element-containing compound may be yttrium oxide, and the magnesium-containing compound may be magnesium oxide, and wherein the mixed raw material powder may include 2 to 5 mol % of yttrium oxide and 2 to 10 mol % of magnesium oxide.

In addition, during nitrifying, the nitrogen gas may be applied at a pressure of 0.1 to 0.2 MPa.

In addition, during nitrifying, the granules may be heated at a temperature increase rate of 0.5 to 10° C./min from 1,000° C. or higher to a predetermined temperature.

In addition, the present invention provides an electrostatic chuck heater having a first surface on which a wafer is adsorbed and a second surface opposing thereto, including an electrostatic chuck part including a first ceramic sintered body, one surface of which is the first surface, and an electrostatic electrode which is laid in the first ceramic sintered body; and a heater part including a second ceramic sintered body, one surface of which is the second surface, and at least one resistance heating element which is laid inside the second ceramic sintered body, wherein at least any one of the first ceramic sintered body and the second ceramic sintered body is provided with a plasma-resistant and corrosion-resistant silicon carbide (SiC) surface modification layer on at least a portion of the external surface.

According to an exemplary embodiment of the present invention, the first ceramic sintered body and the second ceramic sintered body may be simultaneously sintered and implemented as one body.

In addition, the present invention provides a semiconductor holding device, including the electrostatic chuck heater according to the present invention; and a cooling member which is disposed on a second surface side of the electrostatic chuck heater.

### Advantageous Effects

Since the electrostatic chuck according to the present invention is provided with a silicon nitride ceramic sintered body, it exhibits the same or similar heat dissipation performance compared to an aluminum nitride ceramic sintered body, which has been widely used in the past, while exhibiting excellent plasma resistance, chemical resistance and thermal shock resistance, and thus, it can be widely used in semiconductor processes.

In addition, the electrostatic chuck according to the present invention can secure more excellent plasma resistance, as a silicon carbide (SiC) surface modification layer is formed on the external surface of the ceramic sintered body, which is silicon nitride, by carburizing or oxidizing.

### DESCRIPTION OF DRAWINGS

FIG. 1 is a cross-sectional mimetic diagram of an electrostatic chuck according to an exemplary embodiment of the present invention; and

FIG. 2 is a cross-sectional view mimetic of an electrostatic chuck heater according to an exemplary embodiment of the present invention.

### MODES OF THE INVENTION

Hereinafter, the exemplary embodiments of the present invention will be described in detail so that those skilled in the art can easily practice the present invention. The present invention may be embodied in many different forms and is not limited to the exemplary embodiments set forth herein.

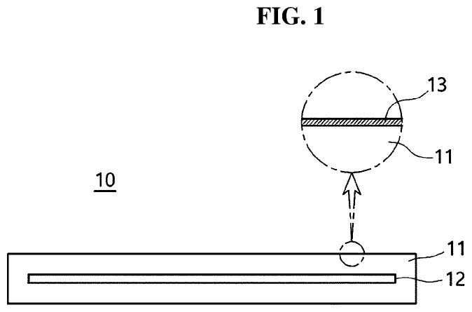

Referring to FIG. 1, the electrostatic chuck 10 according to an exemplary embodiment of the present invention is implemented by including a silicon nitride sintered body 11, a surface modification layer 13 and an electrostatic electrode 12.

The electrostatic chuck 10 is a device that adsorbs and holds an object, for example, a semiconductor wafer by electrostatic attraction, and is used, for example, to fix a semiconductor wafer in the semiconductor manufacturing process. The electrostatic chuck 10 may have a support surface conforming to the shape of an object to be gripped, and for example, the electrostatic chuck 10 may have a disk shape to conform to the shape of a wafer. In addition, the size of the electrostatic chuck 10 may be the size of a typical electrostatic chuck used in semiconductor manufacturing, but the present invention is not limited thereto.

The silicon nitride sintered body 11 corresponds to the body of the electrostatic chuck 10, and serves to support the electrostatic electrode 12 laid therein and to provide a support surface for adsorbing an object such as a semiconductor wafer. Since the silicon nitride sintered body 11 has excellent plasma resistance, chemical resistance, thermal shock resistance and excellent heat dissipation characteristics, it may be particularly useful for electrostatic chucks used in semiconductor processes.

According to an exemplary embodiment of the present invention, the silicon nitride sintered body 11 may be implemented through silicon nitride powder which is prepared by the preparation method described below to express more improved characteristics in the above-described physical properties.

Specifically, the silicon nitride powder may be prepared by including the steps of preparing mixed raw material powder including metallic silicon powder and crystalline phase control powder which includes a rare earth element-containing compound and a magnesium-containing compound; mixing the mixed raw material powder with a solvent and an organic binder to form a slurry and then spray-drying to produce granules having a predetermined particle size; nitrifying the granules at a predetermined temperature within the range of 1,200 to 1,500° C. while applying nitrogen gas at a predetermined pressure; and pulverizing the nitrified granules.

First of all, the step of preparing mixed raw material powder including metallic silicon powder and crystalline phase control powder which includes a rare earth element-containing compound and a magnesium-containing compound will be described.

As the raw material powder, the main metallic silicon powder may be used without limitation in the case of metallic silicon powder which is capable of preparing silicon nitride powder through the direct nitrifying method. For example, the metallic silicon powder may be a polycrystalline metal silicon scrap or single crystal silicon wafer scrap. The polycrystalline metal silicon scrap may be a by-product of polycrystalline metal silicon used for semiconductor processing fixtures or solar panel manufacturing, and the single-crystal silicon wafer scrap may also a by-product during silicon wafer manufacturing, and therefore, through using these scraps, which are by-products, as the raw material powder. it is possible to lower the manufacturing cost.

In addition, the polycrystalline metal silicon scrap or single crystal silicon wafer scrap may have a purity of 99% or more, and it may be more advantageous to ensure thermal conductivity and mechanical strength of the sintered body when sintering the silicon nitride powder prepared through this.

In addition, the metallic silicon powder may have a resistivity of 1 to 100 Ωcm, and through this, it may be more advantageous in terms of preparing silicon nitride powder having desired physical properties of the present invention.

Meanwhile, the metallic silicon powder used as the raw material powder may preferably be a pulverized polycrystalline metal silicon scrap or single crystal silicon wafer scrap into a predetermined size. In this case, in order to prevent contaminants such as metal impurities due to pulverization from being mixed into the raw material powder, the pulverization may use a dry pulverization method, and specifically, it may be powdered by using dry grinding methods such as disk mill, pin mill and jet mill. If contaminants are contained in the metallic silicon powder, there is a concern of increasing manufacturing time and cost due to further washing processes such as acid washing to remove contaminants. In this case, the average particle diameter of the pulverized metallic silicon powder may be 0.5 to 4 μm, and more preferably 2 to 4 μm, and if the average particle diameter is less than 0.5 μm, it may be difficult to implement through the dry pulverizing method. In addition, there is a concern that the possibility of mixing of contaminants may increase due to fine powder, and densification may be difficult during sheet casting. In addition, if the average particle diameter of the metallic silicon powder is more than 4 μm, nitrifying is not easy, and thus, there is a concern that non-nitrified portions may exist, and densification of the final sintered body may be difficult.

Meanwhile, silicon nitride is difficult for self-diffusion and may be thermally decomposed at high temperatures, and thus, sintering is not easy due to limitations in sintering temperature, and it is difficult to realize a dense sintered body. Additionally, when preparing silicon nitride powder by the direct nitrifying method, it may be difficult to control the crystalline phase. Therefore, in order to solve these difficulties and improve the physical properties of a substrate on which the silicon nitride powder is sintered by removing impurities such as oxygen, a mixed raw material powder obtained by mixing a crystalline phase control powder with metallic silicon powder is used as a raw material powder. The crystalline phase control powder may be, for example, a rare earth element-containing compound, an alkaline earth metal oxide and a combination thereof, and specifically, at least one selected from the group consisting of magnesium oxide (MgO), yttrium oxide (Y₂O₃), gadolinium oxide (Gd₂O), holmium oxide (Ho₂O₃), erbium oxide (Er₂O₃), ytterbium oxide (Yb₂O₃) and dysprosium oxide (Dy₂O₃) may be used. However, in the present invention, in order to more easily control the crystalline phase of the silicon nitride powder, magnesium oxide and yttrium oxide are essentially contained in the crystalline phase control powder, and the magnesium oxide and yttrium oxide have the advantages of realizing a more dense, high-density sintered body when preparing a sintered body by using the prepared silicon nitride powder, and reducing the amount of residual grain boundary phases during sintering, thereby improving the thermal conductivity of the sintered body.

For example, the mixed raw material powder may include 2 to 5 mol % of the yttrium oxide and 2 to 10 mol % of the magnesium oxide. If the amount of yttrium oxide is less than 2 mol %, it may be difficult to implement a densified sintered body when sintering the implemented silicon nitride powder, and it is difficult to capture oxygen on the grain boundary, and as a result, since the amount of dissolved oxygen increases, the thermal conductivity of the sintered body may be lowered, and the mechanical strength may also be reduced. In addition, if the amount of yttrium oxide is more than 5 mol %, there is a concern that the thermal conductivity and fracture toughness of the sintered body obtained by sintering the silicon nitride powder are reduced due to an increase of grain boundary phases. In addition, when the amount of magnesium oxide is less than 2 mol %, both of thermal conductivity and mechanical strength of the sintered body obtained by sintering the silicon nitride powder may be low, and there is a risk of silicon elution during nitrifying, and it may be difficult to prepare a densified sintered body. In addition, if the amount of magnesium oxide is more than 10 mol %, the residual amount of magnesium increases at the grain boundary during sintering, and as a result, the thermal conductivity of the implemented sintered body may be lowered, the sintering of the silicon nitride powder may not be easy, and the fracture toughness may be reduced.

In addition, the rare earth element-containing compound powder, which has an average particle diameter of 0.1 to 1 μm, may be used, and the magnesium-containing compound powder, which has an average particle diameter of 0.1 to 1 μm, may be used, and through this, it may be more advantageous to achieve the objects of the present invention.

Next, the step of mixing the prepared mixed raw material powder with a solvent and an organic binder to form a slurry and then spray-drying to produce granules having a predetermined particle size is performed.

Instead of immediately nitrifying the mixed raw material powder, after it is produced into granules having a predetermined particle size, the granules are subjected to a nitrifying process, which will be described below, and through this, the crystalline phase of the prepared silicon nitride powder may be more easily controlled by increasing the mixing uniformity of the mixed raw material powder, and since it is possible to form a secondary phase of Si₂Y₂O₅, the thermal conductivity of the sintered body may be further improved, and it is possible to prepare silicon nitride powder having uniform characteristics.

The granules may have a D50 value of 100 μm or less, more preferably, 20 to 100 μm, and even more preferably, 20 to 55 μm. If the D50 exceeds 100 μm, the inflow of nitrogen gas into the granules is not smooth such that nitrifying does not occur completely, and silicon that is not nitrified may be melted and eluted out of the granules. When such silicon nitride powder is prepared into a sintered body, there is a concern that silicon that has been eluted during the preparation of silicon nitride powder may be eluted out again during the sintering process of the sintered body. Herein, the D50 value means a value on a 50% volume basis as measured by using the laser diffraction scattering method.

Meanwhile, since the granules can be obtained through dry spraying and can be obtained by using known conditions and equipment that are capable of performing dry spraying, the present invention is not particularly limited thereto. In addition, the mixed raw material powder is implemented as a slurry mixed with a solvent and an organic binder and then dry sprayed, and in the case of a solvent and an organic binder used during slurrying in order to implement ceramic powder, the solvent and organic binder may be used without limitation. For example, it is preferable that the solvent includes at least one selected from ethanol, methanol, isopropanol, distilled water and acetone. In addition, it is preferable to use a polyvinyl butyral (PVB)-based binder as the organic binder. Meanwhile, when the organic binder is contained in the production of granules but is contained in a small amount, a separate degreasing process may not be performed prior to the nitrifying process described below.

Next, the step of nitrifying the obtained granules at a predetermined temperature within the range of 1,200 to 1,500° C. while applying nitrogen gas at a predetermined pressure is performed.

In this case, during the nitrifying treatment, the nitrogen gas may be applied at a pressure of 0.1 to 0.2 MPa, and more preferably, at a pressure of 0.15 to 0.17 MPa. If the pressure of nitrogen gas is less than 0.1 MPa, nitrification may not occur completely. In addition, when the pressure of nitrogen gas exceeds 0.2 MPa, a phenomenon in which silicon is eluted during the nitrifying process occurs. In addition, during nitrifying treatment, heating may be performed at a temperature increase rate of 0.5 to 10° C./min from 1,000° C. or higher to a predetermined temperature, and if the temperature increase rate from 1,000° C. or higher to the predetermined temperature is less than 0.5° C./min, the sintering time may be excessively extended. In addition, when the temperature increase rate exceeds 10° C./min, silicon is eluted, and thus, it may be difficult to prepare powder that is completely nitrified with silicon nitride.

In addition, the temperature during nitrifying treatment may be selected within the range of 1,200 to 1,500° C., and if the temperature during nitrifying treatment is less than 1,200° C., nitrifying may not occur uniformly. In addition, since a β crystal phase is quickly formed when the temperature exceeds 1,500° C. during nitrifying, densification may be difficult when preparing a sintered body by using such silicon nitride powder.

Next, the step of pulverizing the nitrified granules is performed.

As a step of preparing nitrified granules into silicon nitride powder, it may be preferably performed by a dry method to prevent the incorporation of contaminants during pulverization, and for example, it may be performed through an air jet mill.

The silicon nitride powder prepared by the above-described preparation method includes 8 wt. % or less of polycrystalline silicon derived from molten silicon, and such silicon nitride powder may be suitable for preparing a sintered body having improved mechanical strength and thermal conductivity. Preferably, the silicon nitride powder may include polycrystalline silicon derived from molten silicon in an amount of 6 wt. % or less, more preferably, 4 wt. % or less, and even more preferably, 0 wt. %.

According to an exemplary embodiment of the present invention, the weight ratio of an α crystal phase in the total weight of an a crystal phase and a β crystal phase may be 0.7 or more, and if the weight ratio of the α crystal phase in the total weight of the α crystal phase and the β crystal phase is less than 0.7, it may be difficult to increase the compactness of the sintered body sintered through the silicon nitride powder, and it may be difficult to improve thermal conductivity and mechanical strength, and particularly, it may be difficult to improve mechanical strength.

In addition, the silicon nitride powder may form a secondary phase of Si₂Y₂O₅ more uniformly on the grain boundary of the sintered body implemented through this, and through this, it is possible to exhibit a synergistic effect in improving the thermal conductivity of the sintered body.

In addition, the silicon nitride powder may have an average particle diameter of 2 to 4 μm, and through this, it may be more advantageous to implement a sintered body having improved mechanical strength and thermal conductivity.

The above-described silicon nitride powder may be formed into a predetermined shape, for example, a disc-shaped molded body, and then subjected to a sintering process to be implemented as a silicon nitride sintered body 11. The molded body may be manufactured by using a known sheet lamination method or press molding method.

When the method for manufacturing a molded body according to the sheet lamination method is described, the slurry obtained by mixing the above-described silicon nitride powder with a solvent and an organic binder may be manufactured by molding into a sheet according to a known method such as the doctor blade method. Thereafter, a molded body may be manufactured by laminating and thermally compressing several sheets of manufactured ceramic green sheets and processing the same into a predetermined size.

In this case, as the solvent provided in the slurry, an organic solvent may be used to dissolve the organic binder and disperse the silicon nitride powder to adjust the viscosity, and as the organic solvent, a material that is capable of dissolving the organic binder may be used without limitation, and for example, terpineol, dihydro terpineol (DHT), dihydro terpineol acetate (DHTA), butyl carbitol acetate (BCA), ethylene glycol, ethylene, isobutyl alcohol, methyl ethyl ketone, butyl carbitol, texanol (2,2,4-trimethyl-1,3-pentanediolmonoisobutyrate), ethylbenzene, isopropylbenzene, cyclohexanone, cyclopentanone, dimethyl sulfoxide, diethyl phthalate, toluene mixtures thereof and the like may be used. In this case, it is preferable to mix 50 to 100 parts by weight of the solvent based on 100 parts by weight of the silicon nitride powder. If the content of the solvent is less than 50 parts by weight, the viscosity of the slurry is high, making it difficult to perform tape casting and difficult to control the coating thickness. If the content of the solvent exceeds 100 parts by weight, the viscosity of the slurry is too thin such that it takes a long time to dry, and it may be difficult to control the thickness.

In addition, it is preferable to mix 5 to 20 parts by weight of the organic binder based on 100 parts by weight of the silicon nitride powder. The organic binder may be a cellulose derivative such as ethyl cellulose, methyl cellulose, nitrocellulose or carboxycellulose, or a polymer resin such as polyvinyl alcohol, acrylic acid ester, methacrylic acid ester or polyvinyl butyral, and considering that a molded body is formed in the shape of a sheet by the tape casting method, polyvinyl butyral may be used as the organic binder.

Meanwhile, the slurry may further include a known material contained in the slurry for forming a sheet, such as a dispersant and a plasticizer, and the present invention is not particularly limited thereto.

Meanwhile, an electrode ink for forming the electrostatic electrode 12 may be treated on one green sheet for manufacturing a molded body such that the electrostatic electrode 12 described below is laid inside the silicon nitride sintered body 11. For the electrode ink, the mixture of a conductive component, a solvent and a binder may be used, but the present invention is not particularly limited thereto.

The implemented molded body may be sintered through a known method to form a silicon nitride sintered body 11, and during the sintering process, the electrode ink provided therein may also be sintered to form an electrostatic electrode 12, thereby manufacturing an electrostatic chuck 10 to be finally obtained. Specifically, the molded body may be sintered at a temperature of 1,800 to 1,900° C. at 0.5 to 1.0 MPa, and through this, it may be more advantageous to implement a high-quality silicon nitride sintered body. In addition, the silicon nitride sintered body 11 thus implemented may have a thermal conductivity of, for example, 70 W/mK or more, preferably, 80 W/mK or more, and even more preferably, 90 W/mK or more, and a 3-point bending strength of 650 MPa or more, preferably, 680 MPa or more, and more preferably, 700 MPa or more.

At least a portion of the external surface of the silicon nitride sintered body 11 described above includes a corrosion-resistant and plasma-resistant surface modification layer 13.

A silicon nitride (Si₃N₄) sintered body has excellent thermal shock resistance, but there is a concern that it may be damaged in a plasma process performed on a wafer and an etching process using hydrofluoric acid or the like. Accordingly, a surface modification layer 13 may be included on at least a portion of the external surface in order to supplement plasma resistance and corrosion resistance to plasma and etching solutions in the plasma process or etching process performed on a wafer.

The surface modification layer 13 may be a layer including silicon carbide (SiC).

Specifically, the silicon carbide (SiC) surface modification layer 13 is formed by modifying the external surface of the silicon nitride sintered body, and in this case, the modification is performed by carburizing or oxidizing, and preferably, carburization.

Carburizing may be a solid carburizing method, a gas carburizing method or a liquid carburizing method, and specifically, the carburizing method of the present invention is a gas carburizing method, and it may be performed under a mixed gas including propane, ammonia, benzene and LPG. Specifically, the carburizing may include propane and ammonia at a flow ratio of 1:0.8 to 1.2, and preferably, 1:0.9 to 1.1, and may include propane and benzene at a flow ratio of 1:0.8 to 1.2, and preferably, 1:0.9 to 1.1, and may include propane and LPG at a flow ratio of 1:0.8 to 1.2, and preferably, 1:0.9 to 1.1.

In addition, the carburizing may be performed at a temperature condition of 700 to 1,100° C., preferably, 800 to 1,000° C., and more preferably, 850 to 950° C.

In addition, the carburizing may be performed for 5 to 35 hours, preferably, 15 to 30 hours, and more preferably, 25 to 30 hours, and if the carburizing time is less than 5 hours, there may be a problem in the thickness of the modification layer 13 formed by carburizing heat treatment, and if it exceeds 35 hours, there may be a problem of cracking due to a difference in thermal expansion coefficients.

Meanwhile, after performing the carburizing mentioned above, the silicon carbide (SiC) surface modification layer 13 may be formed after washing and drying a surface on which the carburizing has been performed. In this case, drying may be performed for 30 to 90 minutes, and preferably, 45 to 75 minutes at a temperature of 50 to 90° C., and preferably, at a temperature of 60 to 80° C., but the present invention is not limited thereto.

In addition, the oxidation treatment may be performed for 30 to 300 minutes, preferably, 30 to 90 minutes, and more preferably, 60 to 90 minutes at a temperature condition of 500 to 1,300° C., and preferably, 600 to 900° C. under an air atmosphere. If the oxidation treatment temperature is less than 500° C., there may be a problem in synthesis due to less than the thickness of the surface modification layer 13, and if it exceeds 1,300° C., SiO2 may progress, and there may be a problem in plasma resistance.

In addition, the silicon carbide (SiC) surface modification layer 13 may have a thickness of 0.2 nm or more, preferably, 200 to 2,000 nm, and more preferably, 500 to 1,000 nm, and if the thickness is less than 0.2 nm, there may be a problem with plasma resistance.

Meanwhile, the electrostatic chuck of the present invention may have a relative etching rate of 0.9 nm/min or less, preferably, 0.8 nm/min or less, and more preferably, 0.6 to 0.7 nm/min, when the etching rate of a Si wafer is 1.0 nm/min, under plasma environment with a power of 500 W or more, preferably, 500 to 700 W, and more preferably, 550 to 650 W, a mixed gas including 10 to 100 sccm, preferably, 10 to 50 sccm, and more preferably, 30 sccm of CF₄ gas, 0.1 to 50 sccm, preferably, 1 to 20 sccm, and more preferably, 5 sccm of of O₂ gas and 1 to 70 sccm, preferably, 5 to 30 sccm, and more preferably, 10 sccm of Ar gas, and a pressure of 1 to 30 m Torr, preferably, 5 to 20 mTorr, and more preferably, 10 mTorr.

Next, the electrostatic electrode 12 which is laid in the silicon nitride sintered body 11 described above will be described.

The electrostatic electrode 12 plays a role of holding a semiconductor wafer on the silicon nitride sintered body 11 by generating an electrostatic force between an object to be attracted, for example, a semiconductor wafer and the silicon nitride sintered body 11. The electrostatic force may be of the Coulomb or Johnson-Rabek type.

The electrostatic electrode 12 may be a material of an electrostatic electrode provided in a typical electrostatic chuck, and may be formed of, for example, a conductive component such as tungsten or molybdenum. In addition, the electrostatic electrode 12 may be provided as a single-surface electrode or as a pair of internal electrodes, but the present invention is not limited thereto, and it may be laid in the silicon nitride sintered body 11 in the number, shape and size of electrostatic electrodes provided in a conventional electrostatic chuck.

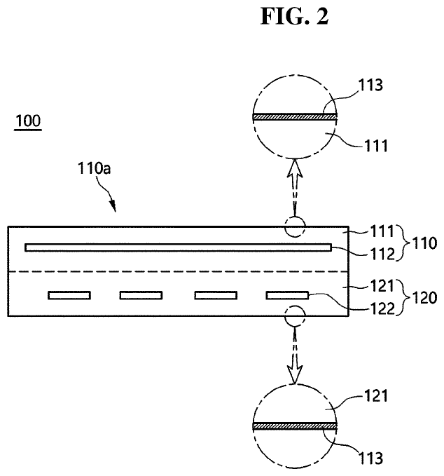

The present invention includes an electrostatic chuck heater which is implemented using the above-described electrostatic chuck. Referring to FIG. 2, the electrostatic chuck heater 100 is implemented by including an electrostatic chuck part 110 that adsorbs and fixes an object to be adsorbed by using electrostatic force, and a heater part 120 having a function of generating heat to be supplied to the object to be adsorbed. In addition, the electrostatic chuck heater 100 has a first surface on which an object to be attracted, for example, a semiconductor wafer, is absorbed and a second surface opposing thereto, and the first surface becomes any one surface of the electrostatic chuck part 110, and the electrostatic chuck part 110 and the heater part 120 are positioned such that the second surface becomes any one surface of the heater part 120.

The electrostatic chuck part 110 includes a first ceramic sintered body 111, a plasma-resistant and corrosion-resistant surface modification layer 113 which is formed on at least a portion of the external surface of the first ceramic sintered body 111, and an electrostatic electrode 112 which is laid inside the first ceramic sintered body 111, and the heater part 120 includes a second ceramic sintered body 121, a plasma-resistant and corrosion-resistant surface modification layer 113 which is formed on at least a portion of the external surface of the second ceramic sintered body 121, and at least one resistance heating element 122 which is laid inside the second ceramic sintered body 121. In this case, at least any one of the first ceramic sintered body 111 and the second ceramic sintered body 121 may be provided as a silicon nitride sintered body, and preferably, it may be the silicon nitride sintered body 11 of the electrostatic chuck 10 described above.

In addition, preferably, both of the first ceramic sintered body 111 and the second ceramic sintered body 121 may be silicon nitride sintered bodies. Accordingly, the silicon nitride sintered body has a plasma-resistant and corrosion-resistant surface modification layer 113 on at least a portion of the external surface. However, although FIG. 2 illustrates that the surface modification layer 113 is provided on the external surfaces of the first ceramic sintered body 111 and the second ceramic sintered body 121, the present invention is not limited thereto, and the surface modification layer 133 may not be provided in any one sintered body among the first ceramic sintered body 111 and the second ceramic sintered body 121.

Meanwhile, when only any one of the first ceramic sintered body 111 and the second ceramic sintered body 121 is a silicon nitride sintered body, the other one may be a ceramic sintered body that is employed in a conventional electrostatic chuck heater, and the present invention is not particularly limited thereto.

In addition, the first ceramic sintered body 111 and the second ceramic sintered body 121 may be simultaneously sintered together to be implemented as one body. That is, for the first ceramic sintered body 111 and the second ceramic sintered body 121, after manufacturing ceramic components into green sheets as described in the preparation method of the silicon nitride sintered body 11 as described above, these are laminated to prepare a sintered body, and green sheets forming the first ceramic sintered body 111 and green sheets forming the second ceramic sintered body 121 may be laminated to manufacture a single molded body, and by simultaneously sintering the same, it is possible to implement a ceramic sintered body that is integrated into one body. However, the present invention is not limited thereto, and it is noted that the first ceramic sintered body 111 and the second ceramic sintered body 121 may be manufactured independently and then integrated by being attached using a known adhesive method.

Meanwhile, a separate intermediate layer (not illustrated) having a composition different from those of the first ceramic sintered body 111 and the second ceramic sintered body 121 may be further included between the first ceramic sintered body 111 and the second ceramic sintered body 121, and through this, it is possible to prevent the leakage of current transmitted from any one side of the electrostatic electrode 112 and the resistive heating element 122 to the other side. Alternatively, when the first ceramic sintered body 111 and the second ceramic sintered body 121 have different compositions, it is possible to prevent the diffusion of a certain component from any one side of the sintered body to the other side of the sintered body.

In addition, the electrostatic chuck part 110 includes an electrostatic electrode 112, and the electrostatic electrode 112 may be made of an electrostatic electrode material provided in a conventional electrostatic chuck, and may be, for example, molybdenum or tungsten.

In addition, the heater part 120 is provided with a resistance heating element 122 inside the second ceramic sintered body 121, and the resistance heating element 122 may be employed without limitation by using a heating element in a conventional electrostatic chuck heater, and for example, it may be formed of a conductive material such as tungsten or molybdenum. In this case, as illustrated in FIG. 2, several resistance heating elements 122 may be laid inside the second ceramic sintered body 121, or one resistance heating element may be implemented in various shapes such as a spiral. Meanwhile, as a specific pattern in which the resistance heating element 122 is laid, the pattern of a resistance heating element in a conventional electrostatic chuck heater may be employed without limitation, and thus, the present invention is not particularly limited thereto.

In addition, the present invention includes a semiconductor holding device including the electrostatic chuck heater 100 according to the present invention described above and a cooling member which is disposed on a second surface side of the electrostatic chuck heater 100.

The cooling member is for controlling the temperature of the semiconductor wafer held on the electrostatic chuck heater 100, and it may serve to cool the semiconductor wafer heated through the heater part 120. The cooling member may be used without limitation in the case of a cooling member that is commonly employed in a semiconductor holding device. For example, the cooling member may be formed with a cooling substrate formed of aluminum or titanium and a passage through which a refrigerant may flow is formed inside the cooling substrate.

In addition, the semiconductor holding device may employ known constitutions that are employed in a semiconductor holding device other than other than the electrostatic chuck heater 100 and the cooling member, for example, known constitutions such as a power source that is capable of applying current to the electrostatic electrode 112 and the resistance heating element 122 of the electrostatic chuck heater 100, a focus ring placement table that is provided with an electrostatic chuck for the focus ring, an installation plate supporting the same and the like, and the present invention is not particularly limited thereto.

Although one exemplary embodiment of the present invention has been described above, the spirit of the present invention is not limited to the exemplary embodiments presented herein, and those skilled in the art who understand the spirit of the present invention may easily suggest other exemplary embodiments by changing, modifying, deleting or adding components within the scope of the same spirit, but this will also fall within the scope of the present invention.

### Preparation Example 1: Oxidation Treatment of Silicon Nitride (Si₃N₄) Sintered Body

A silicon nitride (Si₃N₄) sintered body was prepared.

The prepared silicon nitride sintered body was introduced into a box furnace, and oxidation treatment was performed for 60 minutes at a temperature of 600° C. under an air atmosphere to form a silicon carbide (SiC) surface modification layer on a portion of the external surface of the silicon nitride sintered body.

### Preparation Example 2: Oxidation Treatment of Silicon Nitride (Si₃N₄) Sintered Body

A silicon nitride (Si₃N₄) sintered body was prepared.

The prepared silicon nitride sintered body was introduced into a box furnace, and oxidation treatment was performed for 60 minutes at a temperature of 1,000° C. under an air atmosphere to form a silicon carbide (SiC) surface modification on a portion of the external surface of the silicon nitride sintered body.

### Preparation Example 3: Oxidation Treatment of Silicon Nitride (Si₃N₄) Sintered Body

A silicon nitride (Si₃N₄) sintered body was prepared.

The prepared silicon nitride sintered body was introduced into a box furnace, and oxidation treatment was performed for 60 minutes at a temperature of 1,200° C. under an air atmosphere to form a silicon carbide (SiC) surface modification layer on a portion of the external surface of the silicon nitride sintered body.

### Preparation Example 4: Performance of Carburizing of Silicon Nitride (Si₃N₄) Sintered Body

A silicon nitride (Si₃N₄) sintered body was prepared.

After spraying carbon powder on a portion of the external surface of the prepared silicon nitride sintered body, the liquid carburizing method of impregnating the same in a wet solution (NaCN 60 wt. %+KCN 40 wt. %) for 9 hours was performed, and a silicon carbide (SiC) surface modification layer was formed on a portion of the external surface of the silicon nitride sintered body.

### Preparation Example 5: Performance of Carburizing of Silicon Nitride (Si₃N₄) Sintered Body

A silicon nitride (Si₃N₄) sintered body was prepared.

The liquid carburizing method of impregnating the prepared silicon nitride sintered body in a wet solution (NaCN 60 wt. %+KCN 40 wt. %) for 9 hours was performed to form a silicon carbide (SiC) surface modification layer on a portion of the external surface of the silicon nitride sintered body.

### Preparation Example 6: Performance of Carburizing of Silicon Nitride (Si₃N₄) Sintered Body

A silicon nitride (Si₃N₄) sintered body was prepared.

After spraying carbon powder on a portion of the external surface of the prepared silicon nitride sintered body, gas carburization was performed for 12 hours at a temperature of 900° C. under a mixed gas including propane, ammonia, benzene and LPG at a flow ratio of 1:1:1:1 to form a silicon carbide (SiC) surface modification layer on a portion of the external surface of the silicon nitride sintered body.

### Preparation Example 7 Performance of Carburizing of Silicon Nitride (Si₃N₄) Sintered Body

A silicon nitride (Si₃N₄) sintered body was prepared.

For the prepared silicon nitride sintered body, gas carburization was performed for 12 hours at a temperature of 900° C. under a mixed gas including propane, ammonia, benzene and LPG at a flow ratio of 1:1:1:1 to form a silicon carbide (SiC) surface modification layer on a portion of the external surface of the silicon nitride sintered body.

### Experimental Example 1: Measurement of Etching Depth and Etching Rate of Silicon Carbide Surface Modification Layer and Relative Etching Rate when the Etching Rate of Si Wafer is 1.0 nm/Min

For each of the silicon carbide (SiC) surface modification layers formed in Preparation Examples 1 to 7, the etching depth, the etching rate and the relative etching rate when the etching rate of the Si wafer was 1.0 nm/min were measured under the measurement conditions described below, and the results are shown in Table 1.

### *Measurement Conditions*

Measurement equipment: NIE 150

Basic operating mechanism of measurement equipment: Inductively Coupled Plasma (ICP)

Plasma environment: power 600 W, mixed gas in which CF₄ gas 30 sccm, O₂ gas 5 sccm, Ar gas 10 sccm are mixed, pressure 10 mTorr, exposure time 60 minutes (Etching 5 min/Delay 5 min/12 Step)

TABLE 1

| | Etching depth | Etching rate | Relative etching rate |
|---|---|---|---|
| Classification | (μm) | (nm/min) | (nm/min) |
| Preparation | 12.16 | 202.70 | 0.70 |
| Example 1 | | | |
| Preparation | 12.52 | 208.67 | 0.72 |
| Example 2 | | | |
| Preparation | 11.69 | 194.82 | 0.68 |
| Example 3 | | | |
| Preparation | 13.62 | 226.95 | 0.79 |
| Example 4 | | | |
| Preparation | 13.07 | 217.77 | 0.76 |
| Example 5 | | | |
| Preparation | 11.26 | 187.75 | 0.65 |
| Example 6 | | | |
| Preparation | 11.22 | 186.99 | 0.65 |
| Example 7 | | | |

1. An electrostatic chuck, comprising:
a silicon nitride (Si₃N₄) sintered body;
a silicon carbide (SiC) surface modification layer covering at least a portion of the external surface of the silicon nitride sintered body and having corrosion resistance and plasma resistance; and
an electrostatic electrode laid inside the silicon nitride sintered body

2. The electrostatic chuck of claim 1, wherein the electrostatic chuck has a relative etching rate of 0.9 nm/min or less when the etching rate of a Si wafer is 1.0 nm/min, under plasma environment with a power of 500 W or more, a mixed gas comprising 10 to 100 sccm of CF₄ gas, 0.1 to 50 sccm of O₂ gas and 1 to 70 sccm of Ar gas, and a pressure of 1 to 30 mTorr.

3. The electrostatic chuck of claim 1, wherein the silicon carbide (SiC) surface modification layer is formed by modifying an external surface of the silicon nitride sintered body, and
wherein the modification is performed by carburizing or oxidizing.

4. The electrostatic chuck of claim 3, wherein the carburizing is performed for 5 to 35 hours at a temperature of 700 to 1,100° C. under a mixed gas comprising propane, ammonia, benzene and LPG.

5. The electrostatic chuck of claim 3, wherein the oxidizing is performed for 30 to 300 minutes at a temperature of 500 to 1,300° C. under an air atmosphere.

6. The electrostatic chuck of claim 1, wherein the silicon carbide (SiC) surface modification layer has a thickness of 0.2 nm or more.

7. The electrostatic chuck of claim 1, wherein the silicon nitride sintered body is formed by sintering silicon nitride powder comprising 8 wt. % or less of polycrystalline silicon.

8. The electrostatic chuck of claim 1, wherein the silicon nitride sintered body is formed by sintering phosphorus silicon nitride powder in which the weight ratio of an α crystal phase is 0.7 or more in the total weight of an α crystal phase and a β crystal phase.

9. The electrostatic chuck of claim 1, wherein the silicon nitride sintered body has a thermal conductivity of 90 W/mK or more and a 3-point bending strength of 700 MPa or more.

10. The electrostatic chuck of claim 1, wherein the silicon nitride sintered body is prepared by sintering silicon nitride powder, and the silicon nitride powder is prepared by comprising the steps of:
preparing mixed raw material powder comprising metallic silicon powder and crystalline phase control powder which comprises a rare earth element-containing compound and a magnesium-containing compound;
mixing the mixed raw material powder with a solvent and an organic binder to form a slurry and then spray-drying to produce granules having a predetermined particle size;
nitrifying the granules at a predetermined temperature within the range of 1,200 to 1,500° C. while applying nitrogen gas at a predetermined pressure; and
pulverizing the nitrified granules.

11. The electrostatic chuck of claim 10, wherein the metallic silicon powder is a dry-ground polycrystalline metal silicon scrap or single-crystal silicon wafer scrap to minimize contamination with metal impurities during pulverizing.

12. The electrostatic chuck of claim 10, wherein the metallic silicon powder has an average particle diameter of 0.5 to 4 μm, the rare earth element-containing compound powder has an average particle diameter of 0.1 to 1 μm, and the magnesium-containing compound powder has an average particle diameter of 0.1 to 1 μm.

13. The electrostatic chuck of claim 10, wherein the granules have a D50 value of 100 μm or less.

14. The electrostatic chuck of claim 10, wherein the rare earth element-containing compound is yttrium oxide, and the magnesium-containing compound is magnesium oxide, and
wherein the mixed raw material powder comprises 2 to 5 mol % of yttrium oxide and 2 to 10 mol % of magnesium oxide.

15. The electrostatic chuck of claim 10, wherein during nitrifying, the nitrogen gas is applied at a pressure of 0.1 to 0.2 MPa.

16. The electrostatic chuck of claim 10, wherein during nitrifying, the granules are heated at a temperature increase rate of 0.5 to 10° C./min from 1,000° C. or higher to a predetermined temperature.

17. An electrostatic chuck heater having a first surface on which a wafer is adsorbed and a second surface opposing thereto, comprising:
an electrostatic chuck part comprising a first ceramic sintered body, one surface of which is the first surface, and an electrostatic electrode which is laid in the first ceramic sintered body; and
a heater part comprising a second ceramic sintered body, one surface of which is the second surface, and at least one resistance heating element which is laid inside the second ceramic sintered body,
wherein at least any one of the first ceramic sintered body and the second ceramic sintered body is provided with a plasma-resistant and corrosion-resistant silicon carbide (SIC) surface modification layer on at least a portion of the external surface.

18. The electrostatic chuck heater of claim 17, wherein the first ceramic sintered body and the second ceramic sintered body are simultaneously sintered and implemented as one body.

19. A semiconductor holding device, comprising:
the electrostatic chuck heater according to claim 16; and
a cooling member which is disposed on a second surface side of the electrostatic chuck heater.
